(19) United States
(12) Patent Application Publication
(10) Pub. No.: US 2026/0212477 A1
(43) Pub. Date: Jul. 23, 2026

(54) LINE SETTING DEVICE AND COMPONENT MOUNTER PROVIDED WITH SAME

(71) Applicant: FUJI CORPORATION, Chiryu (JP)

(72) Inventors: Kenshiro NISHIDA, Handa-shi (JP); Yuta YOKOI, Kariya-shi (JP); Yuki INAURA, Chiryu-shi (JP); Mikiya SUZUKI, Nishio-shi (JP)

(73) Assignee: FUJI CORPORATION, Chiryu (JP)

(21) Appl. No.: 19/136,703

(22) PCT Filed: Dec. 26, 2022
(86) PCT No.: PCT/JP2022/047981

§ 371 Date: Jun. 6, 2025

(51) Int. Cl. G06T 7/00; G06T 7/13; G06T 7/174

(52) U.S. Cl. CPC G06T 7/0004; G06T 7/13; G06T 7/174; G06T 2207/30164

(57) ABSTRACT

A line setting device includes a tentative line setting section to set tentative lines at multiple locations of a component based on a design value; a first captured image input section to input a captured image of the component; a first determination section to, for each of the tentative lines at the multiple locations set by the tentative line setting section, determine whether a boundary between high-luminance pixels and low-luminance pixels is detectable with respect to a pixel group on the tentative line in the captured image input by the first captured image input section; and an actual line determination section to not determine the tentative lines, for which the boundary is determined to be undetectable by the first determination section, as actual lines, and to determine the tentative lines, for which the boundary is determined to be detectable by the first determination section, as the actual lines.

### TECHNICAL FIELD

A technology disclosed in the present description relates to a component mounter for mounting a component on a board. In particular, the technology relates to an image processing technique for setting lines in a captured image in which a component is captured and detecting a boundary between high-luminance pixels and low-luminance pixels with respect to a pixel group on the set line.

### BACKGROUND ART

In a component mounter, an image of a component may be captured with an imaging device in order to accurately mount the component at a designated position on a board. The captured image is subjected to image processing, and the component is mounted on the board based on an image processing result. For example, JP-A-H08-180191 discloses a technique for image processing a captured image. In this image processing technique, a process of detecting a boundary (edge) between high-luminance pixels and low-luminance pixels is executed with respect to a pixel group on a line set in a captured image. Then, when the boundary between the high-luminance pixels and the low-luminance pixels is detected, the position thereof is determined as the boundary between a detection target area (for example, an electrode of a component) and a background area.

### BRIEF SUMMARY

### Technical Problem

In the image processing technique described above, it is necessary to set lines in the detection target area in order to detect the detection target area. As a conventional technique, a method of setting lines in an area desired to be detected by a user based on a design value of a component has been proposed. In this method, regardless of whether an edge can be detected, lines are set in an area (such as an electrode, a mark, or a body) desired to be detected by the user. For this reason, the set lines may include improper lines in which an edge cannot be detected due to an insufficient luminance difference. As a result, the user needs to check for each line that has been set whether an edge can be detected on that line, and needs to delete the improper lines.

The present description provides a technique enabling a user to easily set lines for detecting a detection target area.

### Solution to Problem

A line setting device disclosed in the present description sets lines in a captured image in which a component mounted by a component mounter is captured. This device includes: a tentative line setting section configured to set tentative lines at multiple locations of the component based on a design value of the component; a first captured image input section configured to input the captured image of the component; a first determination section configured to, for each of the tentative lines at the multiple locations set by the tentative line setting section, determine whether a boundary between high-luminance pixels and low-luminance pixels is detectable with respect to a pixel group on the tentative line in the captured image input by the first captured image input section; and an actual line determination section configured to not determine the tentative lines, for which the boundary is determined to be undetectable by the first determination section, as actual lines, and to determine the tentative lines, for which the boundary is determined to be detectable by the first determination section, as the actual lines.

In the line setting device described above, multiple tentative lines are set based on the design value of the component, and the captured image of the component is input. Then, it is determined whether the boundary can be detected for each of the multiple tentative lines. When it is determined that the boundary can be detected, the tentative lines are determined as the actual lines, and when it is determined that the boundary cannot be detected, the tentative lines are not determined as the actual lines. Since it is determined whether the boundary can be detected for the tentative lines by the line setting device, the user can easily set the lines.

In addition, a component mounter disclosed in the present description includes: a component supply section configured to supply a component; an imaging device configured to capture an image of the component supplied by the component supply section; the line setting device configured to set lines in the captured image of the component captured with the imaging device; and a component mounting section configured to mount the component supplied by the component supply section on a board. The component mounting section mounts the component at a mounting position, which is calculated based on the captured image of the component captured with the imaging device and the lines set by the line setting device. With this component mounter, the user can easily set lines in the component mounter.

### BRIEF DESCRIPTION OF DRAWINGS

FIG. 1 is a cross-sectional view illustrating a schematic configuration of a component mounter.

FIG. 2 is a block diagram illustrating a configuration of a seek line setting device (an example of a line setting device) according to an example.

FIG. 3 is a flowchart illustrating a procedure for setting seek lines (an example of lines) by the seek line setting device.

FIG. 4 is an image displayed on a display device of the seek line setting device, in which tentative seek lines (an example of tentative lines) set based on a design value and an image of a component are overlaid and displayed.

FIG. 5 is an image displayed on the display device of the seek line setting device, and is a screen for displaying a result of performing edge detection processing on respective tentative seek lines.

FIG. 6 is an image displayed on the display device of the seek line setting device, in which the finally set actual seek lines (an example of actual lines) and the image of the component are overlaid and displayed.

### DESCRIPTION OF EMBODIMENTS

The line setting device disclosed in the present description may further include a parameter adjustment section that adjusts, for each of the actual lines determined by the actual line determination section, a parameter for detecting the boundary between the high-luminance pixels and the low-luminance pixels with respect to a pixel group on the actual line in the captured image input by the first captured image input section. With this configuration, the adjustment of the parameter for detecting the boundary between the high-luminance pixels and the low-luminance pixels can be performed automatically, and the line setting by a user can be further simplified.

The line setting device disclosed in the present description may further include: a second captured image input section configured to input another captured image different from the captured image input from the first captured image input section; a second determination section configured to, for each of the actual lines set by the actual line setting section, determine whether the boundary between the high-luminance pixels and the low-luminance pixels is detectable with respect to a pixel group on the actual line in the captured image input by the second captured image input section; and an output section configured to output a determination result by the second determination section. With this configuration, it is possible to check whether the actual lines set using the captured image input from the first captured image input section are valid also in another captured image input by the second captured image input section.

### Example

Seek line setting device 50 according to an example will be described with reference to the drawings. Seek line setting device 50 sets seek lines in a captured image (image data) obtained by capturing an image of a component mounted by a component mounter. Before describing seek line setting device 50, first, an example of the component mounter will be briefly described.

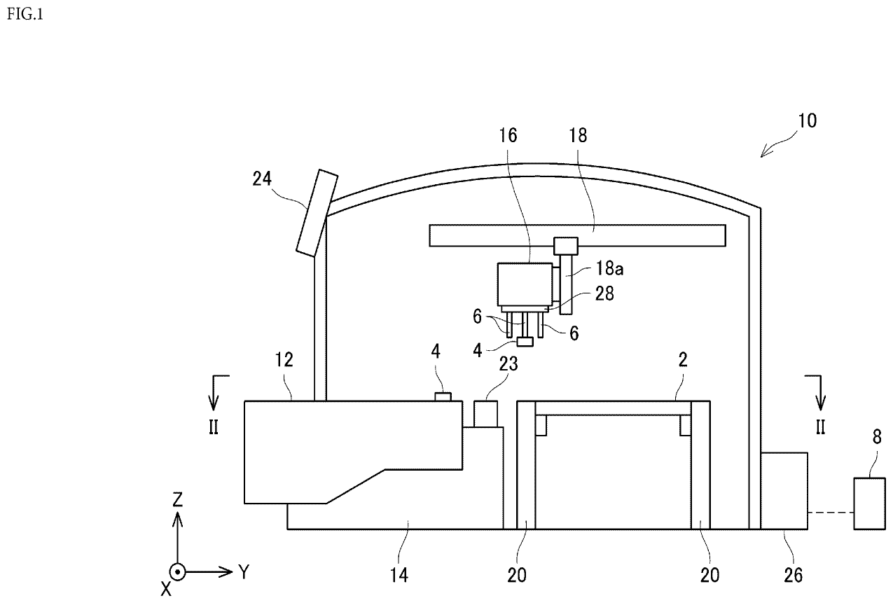

As illustrated in FIG. 1, component mounter 10 is a device configured to mount component 4 on board 2. Component mounter 10 is also referred to as an electronic component mounting device or a chip mounter. Normally, component mounter 10 is provided together with other board work machines, such as a solder printing machine and a board inspection machine, to form a series of mounting lines.

Component mounter 10 includes component feeder 12, feeder holding section 14, component mounting unit (16, 18), board conveyor 20, part camera 23, control device 26, and touch panel 24. Management device 8 that is communicably connected with component mounter 10 is disposed outside component mounter 10.

Component feeder 12 accommodates multiple components 4. Component feeder 12 is detachably attached to feeder holding section 14, and supplies components 4 to component mounting unit (16, 18). Feeder holding section 14 includes multiple slots, and component feeder 12 can be detachably installed in each of the multiple slots. That is, multiple component feeders 12 can be installed in component mounter 10.

Component mounting unit (16, 18) includes head 16 and head moving device 18 that moves head 16. Multiple nozzles 6 are detachably attached to head 16. Each of multiple nozzles 6 can pick up component 4. Nozzle 6 is movable in a Z direction (vertical direction) with respect to lower surface 28 of head 16, and moves nozzle 6 towards and away from component feeder 12 or board 2. Accordingly, head 16 can pick up components 4 supplied from component feeder 12 by nozzles 6 and can place components 4 picked up by nozzles 6 on board 2.

Head moving device 18 moves head 16 between component feeder 12 and board 2. Head moving device 18 is an XY robot that moves moving base 18a in an X direction and a Y direction, and head 16 is fixed to moving base 18a. Head moving device 18 can translate nozzle 6 on the plane (XY plane) parallel to the surface of board 2.

Board conveyor 20 is a device that conveys in, positions, and conveys out board 2. Board conveyor 20 includes a pair of belt conveyors and a supporting device (not illustrated) that supports board 2 from below.

Part camera 23 is a digital imaging device capturing an image of component 4. Part camera 23 is disposed such that an optical axis is directed in the vertical direction (Z-axis direction), and is configured to capture an image of component 4 from below component mounting unit (16, 18). More specifically, part camera 23 is configured to capture an image of the lower surface of component 4 held by nozzle 6.

Control device 26 is configured using a computer including CPU and a memory. Control device 26 controls the operation of each section 12, 16, 18, 20, and 23 of component mounter 10 based on a production program transmitted from management device 8. Accordingly, board 2 is conveyed into component mounter 10 by board conveyor 20, and component mounting unit (16, 18) mounts component 4 on board 2 conveyed in. Board 2 on which component 4 is mounted is conveyed out of component mounter 10 by board conveyor 20. Touch panel 24 is a display device that provides a worker with various information on component mounter 10, as well as an input device that receives instructions or information from the worker.

Control device 26 functions as an image processing device that performs analysis processing on image data of component 4 captured with part camera 23. In order words, the image data obtained by capturing with part camera 23 is input to control device 26. Control device 26 analyzes the image data input from part camera 23 using the seek lines set by seek line setting device 50. The analysis of the image data using the seek lines will be described later.

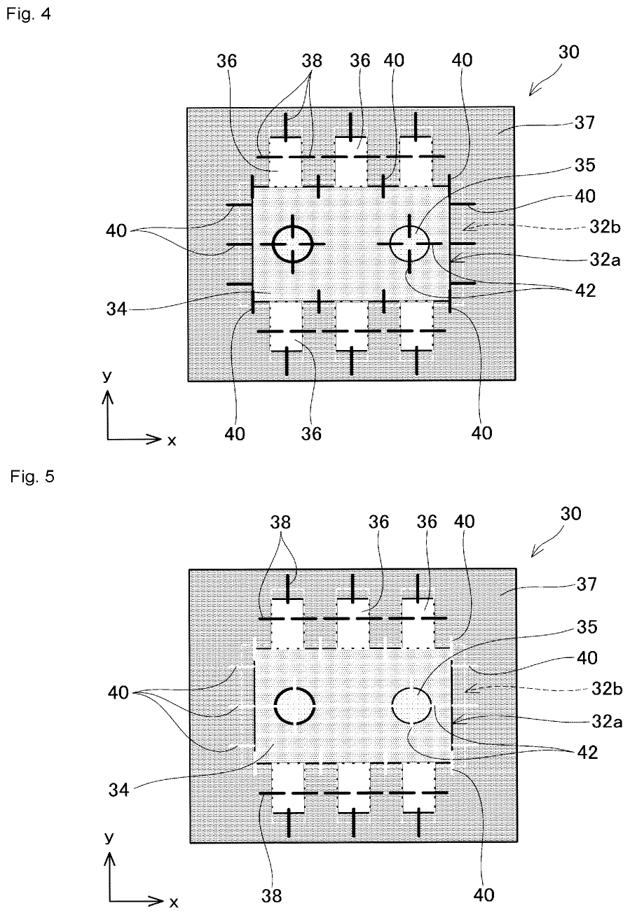

Next, component 4 in which the seek lines are set will be described. In the present example, component 4 on which the seek lines are set may be any component that performs edge detection using the seek lines, and examples thereof include a surface mount component mounted on the surface of board 2. FIG. 4 illustrates an example of component 4 in which the seek lines are set. Since FIG. 4 illustrates an image captured with part camera 23, the bottom surface of component 4 is illustrated in FIG. 4. As illustrated in FIG. 4, component 4 includes rectangular body 34 and three electrodes 36 provided on an upper side and a lower side of body 34. Two circular marks 35 are provided on the bottom surface of body 34 at an interval in an x direction. Three electrodes 36 provided on the upper side are disposed at intervals in the x direction and extend from body 34 in a +y direction. Similarly, three electrodes 36 provided on the lower side are disposed at intervals in the x direction and extend from body 34 in a −y direction. Since electrode 36 is formed of a metal material, electrode 36 reflects light more strongly than body 34. Therefore, in image data 30 illustrated in FIG. 4 (that is, the image data obtained by capturing with part camera 23), the portion of electrode 36 is a portion of the high-luminance pixels, and body 34 and background portion 37 are portions of the low-luminance pixels.

As described above, component 4 has six electrodes 36, and these electrodes 36 need to be bonded to lands printed on the surface of board 2. That is, it is necessary to accurately mount component 4 at the mounting position (the position of the lands) of board 2. However, since the dimensions and shape of component 4 (for example, the position of electrode 36) may deviate from a design value due to tolerances, there may be cases where electrodes 36 of component 4 cannot be bonded to the lands of board 2, even if component 4 is mounted at the mounting position, which is calculated based on the design value. Therefore, in the present example, the lower surface of component 4 is captured with part camera 23, and the dimensions and shape (for example, the position of electrode 36) of component 4 are detected by performing image processing on the captured image. Then, the position where component 4 is to be mounted is corrected based on the detected dimensions and shape of component 4, and component 4 is mounted at the corrected position. As a result, electrodes 36 of component 4 and the lands of board 2 are reliably bonded.

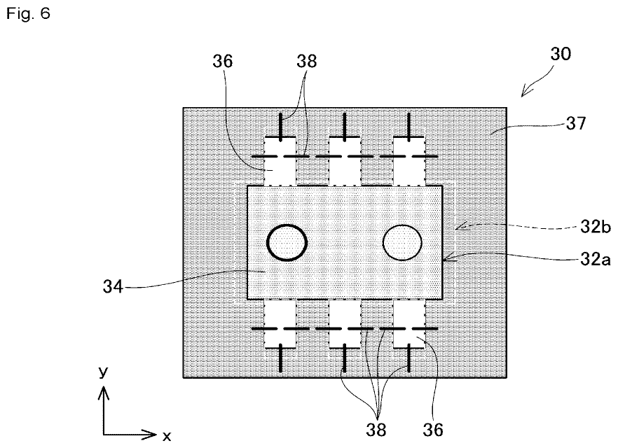

Here, component 4 is often a small component, and the clarity of the image data captured with part camera 23 may be insufficient to accurately detect the dimensions and shape of component 4. In the present example, as illustrated in FIG. 6, seek lines 38 are set at a desired portion (for example, electrode 36) of component 4, and the position of the desired portion of component 4 is detected using seek lines 38. The image processing using seek lines 38 will be described in detail later.

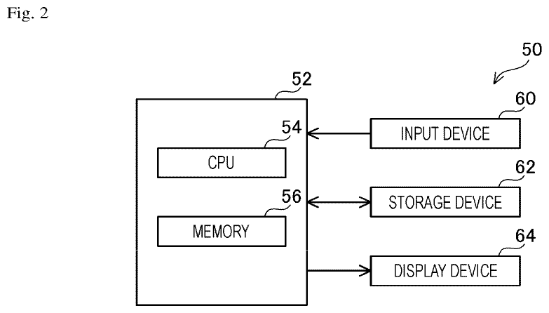

Next, seek line setting device 50 will be described. As illustrated in FIG. 2, seek line setting device 50 includes arithmetic device 52 and various devices (input device 60, storage device 62, and display device 64) connected to arithmetic device 52. Arithmetic device 52 is configured using a computer including CPU 54 and memory 56. CPU 54 executes seek line setting processing (described in detail later) for setting seek lines 38 on component 4 based on the program stored in memory 56. Arithmetic device 52 includes an input/output circuit that inputs the image data of component 4 captured with part camera 23, CAD data of component 4 stored in management device 8, and the like. Memory 56 is configured with a flash memory or the like, and stores various programs executed by CPU 54 and various data (for example, image data and CAD data of component 4) transmitted from part camera 23 or management device 8 to Arithmetic device 52.

Input device 60 is a device for an operator to perform input setting of information necessary for the seek line setting processing, and includes, for example, a keyboard, a mouse, a touch panel, and the like. Storage device 62 is a device that stores the image data obtained by capturing with part camera 23, the CAD data of component 4 input from management device 8, a result obtained from the seek line setting processing, and the like. Storage device 62 is configured with an optical drive device such as a hard disk device. Display device 64 is a device that displays the image data obtained by capturing with part camera 23, a result obtained from the seek line setting processing, and the like.

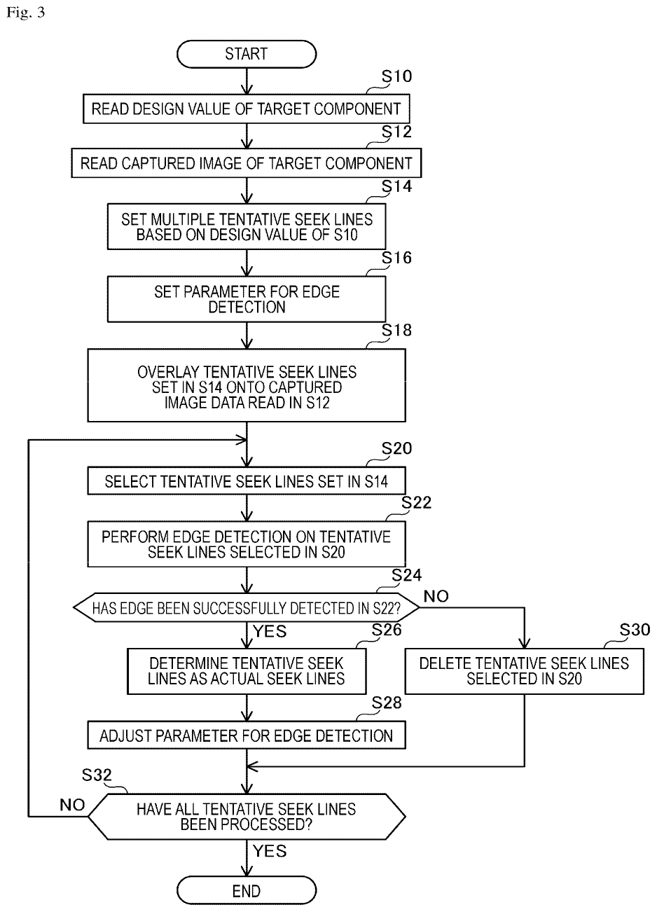

Next, the seek line setting processing executed by CPU 54 of Arithmetic device 52 will be described. As illustrated in FIG. 3, CPU 54 first reads the CAD data of component 4, which is the target for setting the seek lines, from management device 8 (step S10). Specifically, CPU 54 requests management device 8 to transmit the CAD data of component 4, and management device 8 transmits the requested CAD data of component 4 to Arithmetic device 52. The transmitted CAD data of component 4 is input into Arithmetic device 52 via the input/output circuit.

Next, CPU 54 reads the image data of component 4, which is the target for setting the seek lines, into Arithmetic device 52 via the input/output circuit (step S12). As described above, in component mounter 10, the image processing is performed on the image data obtained by capturing component 4 with part camera 23 using the seek lines. Therefore, the image data input to Arithmetic device 52 in S12 is also image data obtained by capturing component 4 with part camera 23. In other words, it is image data captured from below component 4. The image data input in S12 may be directly input from part camera 23, or the image data obtained by capturing with part camera 23 may be stored in an external device (for example, management device 8) and input from the external device to Arithmetic device 52.

Next, CPU 54 executes a process of setting tentative seek lines in component 4 based on the CAD data of component 4 input in S10 (step S14). Specifically, CPU 54 first creates a bottom view of component 4 based on the CAD data input in S10, and displays the created bottom view on display device 64. Next, CPU 54 displays a screen prompting the operator to set the tentative seek lines on display device 64. Accordingly, the operator sets the tentative seek lines using input device 60. When the tentative seek lines are set using input device 60, CPU 54 overlays the tentative seek lines onto the bottom view of component 4 and displays the tentative seek lines on display device 64. This will be specifically described with reference to FIG. 4. In the image displayed on display device 64 in S14, the image data read in S12 is not overlaid, and the image of component 4 indicated by reference numeral 32a in FIG. 4 is not included. In FIG. 4, bottom view 32b of component 4 based on the CAD data is indicated by a dotted line. As described above, component 4 includes body 34 and multiple electrodes 36 extending vertically from body 34. Two marks 35 are formed on body 34. In S14, first, only bottom view 32b indicated by a dotted line is displayed on display device 64. Subsequently, a message such as “Please set tentative seek lines” is displayed on display device 64. Therefore, the operator sets tentative seek lines at a desired position on display device 64. For example, the operator sets each tentative seek line by designating a start point and an end point of the tentative seek line using input device 60 (for example, a mouse). The operator can set the tentative seek line at any position.

In the example illustrated in FIG. 4, three tentative seek lines 38 (that is, two lines extending in the x direction and one line extending in the y direction) are set for each electrode 36. Tentative seek lines 38 set on electrode 36 are set across both electrode 36 and background portion 37. In other words, tentative seek lines 38 are set with the intention of detecting a boundary (edge) between electrode 36 and background portion 37. For rectangular body 34, three tentative seek lines 40 are set on the short side extending in the y direction, and four tentative seek lines 40 are set on the long side extending in the x direction. Tentative seek lines 40 are set across both body 34 and background portion 37, and are intended to detect a boundary (edge) between body 34 and background portion 37. Further, in the example illustrated in FIG. 4, four tentative seek lines 42 are set for mark 35 formed on body 34. Four tentative seek lines 42 extend radially with respect to the center of mark 35 and are disposed at angular intervals of 90° in the circumferential direction. Tentative seek lines 42 are set across both the inside of mark 35 and the outside of mark 35, and are intended to detect a boundary (edge) between the inside and the outside of mark 35.

Next, CPU 54 executes the setting of a parameter to be used when performing edge detection using the seek lines (step S16). In the analysis processing using the seek lines (that is, the edge detection processing), first, the luminance value of each pixel on the seek line is acquired, and the differences in the luminance values between adjacent pixels (hereinafter, simply referred to as a luminance difference) are calculated. Next, from the calculated luminance differences, the pixel with the maximum value of the luminance difference is identified, and the maximum value of the luminance difference is compared with a threshold (that is, a parameter set in S16). When the maximum value of the luminance difference is equal to or greater than the threshold, it is determined that an edge is detected, and when the maximum value of the luminance difference is less than the threshold, it is determined that no edge is detected. When an edge is detected, the pixel with the maximum value of the luminance difference will be the position of the boundary (edge). Therefore, in S16, the threshold, which is the parameter when performing edge detection using the seek lines, is set. The parameter set in S16 may be set based on the experience of the operator, or may be a default value prepared in advance by seek line setting device 50.

Next, CPU 54 displays an image in which the image data of component 4 read in S12 and tentative seek lines 38, 40, and 42 set in S14 are overlaid on display device 64 (step S18). As a result, the operator can check whether tentative seek lines 38, 40, and 42 set in S14 are set at the desired position of the image data. For example, in FIG. 4, image 32a of component 4 based on the image data read in S12, bottom view 32b of component 4 based on the CAD data read in S10, and tentative seek lines 38, 40, and 42 set in S14 are displayed on display device 64. As is clear from FIG. 4, image 32a of component 4 is smaller than bottom view 32b of component 4 based on the CAD data, and part of tentative seek lines 40 (that is, two tentative seek lines 40 positioned at both ends among four tentative seek lines 40 set on the long side of body 34) are not disposed at the desired position (on body 34). Therefore, the operator can review the settings such as changing or canceling the position of tentative seek lines 40 that are not disposed at the desired position. Since the boundary (edge) cannot be detected with such tentative seek lines, the tentative seek lines are not adopted as the actual seek lines, as described later. Therefore, in S18, the operator only needs to check the settings of the tentative seek lines and does not need to review the settings.

Next, CPU 54 selects one of tentative seek lines 38, tentative seek lines 40, or tentative seek lines 42 from among multiple tentative seek lines 38, 40, and 42 set in S14 (step S20), and executes the edge detection processing on selected tentative seek lines (38, 40, or 42) (step S22). As described above, in the edge detection processing, the luminance values of the pixels on the seek lines are acquired, and it is determined whether the maximum value of the luminance difference between the adjacent pixels is equal to or greater than the threshold. Therefore, in S22, it is determined whether the maximum value of the luminance difference between the adjacent pixels on tentative seek lines 38, 40, and 42 set in S14 is equal to or larger than the threshold set in S16 for the image data of component 4 read in S12 (S22).

Next, CPU 54 determines whether an edge (boundary) can be detected by the edge detection processing in S22 (step S24). When the edge (boundary) can be detected in S22 (YES in S24), tentative seek lines (38, 40, or 42) selected in S20 are considered proper seek lines, the tentative seek lines selected in S20 are determined as the actual seek lines (step S26), and the parameter used for the edge detection (that is, the threshold set in S16) is adjusted (step S28). As a result, tentative seek line (38 or 40 or 42) set at the position where the edge detection can be performed is determined as the actual seek line, and the parameter (threshold) for the edge detection is adjusted to a more proper value based on the actual image data. The adjustment of the parameter can be performed by various methods, and for example, when the difference between the maximum value of the luminance difference between the adjacent pixels and the threshold set in S16 is small, the threshold set in S16 is adjusted so that the difference becomes large. Accordingly, the edge detection can be stably performed. Alternatively, an average value of luminance differences between all adjacent pixels on the tentative seek line may be calculated, and the threshold may be set to be larger than the average value.

On the other hand, when the edge (boundary) cannot be detected in the tentative seek lines selected in S20 (NO in S24), tentative seek lines (38, 40, or 42) selected in S20 are considered improper seek lines, and the tentative seek lines selected in S20 are deleted (step S30). As a result, the improper tentative seek lines are automatically deleted.

Next, CPU 54 determines whether the processing of S22 to S28 has been executed for all tentative seek lines 38, 40, and 42 set in S14 (step S32). When the processing of S22 to S28 has not been executed for all tentative seek lines 38, 40, and 42 (NO in S32), CPU 54 returns to S20 and repeats the processing from step S20. As a result, the processing of S22 to S28 is executed for all tentative seek lines 38, 40, and 42 set in S14. When the processing of S22 to S28 has been executed for all tentative seek lines 38, 40, and 42 (YES in S32), CPU 54 displays the result of the seek line setting processing (FIGS. 5 and 6) on display device 64, and completes the seek line setting processing.

In FIG. 5, tentative seek lines 38, 40, and 42 after the seek line setting processing is completed and image data 30 are overlaid and displayed. As illustrated in FIG. 5, since the luminance difference between electrode 36 and background portion 37 is large, tentative seek lines 38 (depicted as black solid lines) succeed in edge detection and are determined as the actual seek lines. In other words, since electrode 36 is formed of metal, electrode 36 is an area with high luminance, resulting in a large luminance difference with background portion 37. Therefore, the edge detection is successful in tentative seek lines 38. On the other hand, in tentative seek lines 40 (depicted as white solid lines), tentative seek lines 40 positioned at both ends of the long sides are improperly positioned, resulting in no luminance difference, and the remaining tentative seek lines 40 have a small luminance difference between body 34 and background portion 37. For this reason, the edge detection fails for all tentative seek lines 40 (depicted as white solid lines), and tentative seek lines 40 are deleted, resulting in all tentative seek lines 40 being depicted as white solid lines. Also in tentative seek lines 42 (depicted as white solid lines), since the luminance difference between the inside and the outside of mark 35 of body 34 is small, the edge detection fails and tentative seek lines 42 are deleted. As a result, as illustrated in FIG. 6, only seek lines 38 set in the portion of electrode 36 are set as valid actual seek lines. Seek lines 38 set by the seek line setting processing are transmitted to control device 26 of component mounter 10 and used in the image processing executed by control device 26.

The adjustment of the parameter (threshold) in S28 is performed for all tentative seek lines 38. Different parameters (thresholds) may be used for each of tentative seek lines 38, or a common parameter (threshold) may be used for all tentative seek lines 38. In other words, a proper range (that is, condition) of the parameter (threshold) may be obtained in advance for all tentative seek lines 38, and a value satisfying all the proper conditions may be determined as the parameter (threshold).

As is clear from the above description, in seek line setting device 50 of the present example, tentative seek lines 38, 40, and 42 are set based on the CAD data of component 4, and the edge detection is performed on the image data of component 4 captured with part camera 23 using set tentative seek lines 38, 40, and 42. Then, tentative seek lines 40 and 42 for which the edge detection has failed are deleted, and only tentative seek lines 38 for which the edge detection has succeeded are determined as the actual seek lines. Therefore, the operator only needs to set tentative seek lines 38, 40, and 42 based on the CAD data, and does not need to determine whether respective tentative seek lines 38, 40, and 42 are proper seek lines. For the determined actual seek lines, the parameter (threshold) to be used for edge detection is automatically adjusted based on the result of edge detection performed on the actual image data. As a result, the workload for the operator in setting the seek lines can be significantly reduced.

In the example described above, Arithmetic device 52 that executes S12 is an example of the “first captured image input section”, Arithmetic device 52 that executes S14 is an example of the “tentative line setting section”, Arithmetic device 52 that executes S22 and S24 is an example of the “first determination section”, Arithmetic device 52 that executes S26 and S30 is an example of the “actual line determination section”, and Arithmetic device 52 that executes S28 is an example of the “parameter adjustment section”.

In the example described above, the image data captured with part camera 23 of component mounter 10 is input to seek line setting device 50, but the technique disclosed in the present description is not limited to such an embodiment. For example, component 4 may be captured with a camera supported by a camera stand, and the obtained image data may be input to seek line setting device 50. In this case, the capturing environment and capturing conditions when capturing component 4 with the camera supported by the camera stand may be the same as the capturing environment and capturing conditions of component mounter 10.

In seek line setting device 50 of the example described above, tentative seek lines 38, 40, and 42 are set for the image read in step S12, and the process of determining actual seek lines 38 from among set tentative seek lines 38, 40, and 42 is performed, but seek line setting device 50 is not limited to such a usage method. For example, when the actual seek lines are set for a component, seek line setting device 50 can also be used as a device configured to further determine whether the set actual seek lines are proper. For example, when the actual seek lines are set by the seek line setting processing described above, Arithmetic device 52 further reads another image data (image data of component 4), and executes the edge detection processing on the read image data using the actual seek lines set by the seek line setting processing. When the edge detection is successful, the fact that the edge detection is successful is displayed on display device 64. On the other hand, when the edge detection fails, the fact that the edge detection fails is displayed on display device 64. Accordingly, the operator can perform necessary correction or the like on the actual seek lines set by the seek line setting processing.

Although seek line setting device 50 is provided separately from component mounter 10 in the example described above, the technique disclosed in the present description is not limited to such an example. For example, control device 26 of component mounter 10 may be equipped with the function of seek line setting device 50 so that the seek lines can be set by control device 26 of component mounter 10. In this case, touch panel 24 can be used to set the tentative seek lines in S14 and the parameter in S16.

In addition, in the example described above, a linear seek line is set across two adjacent areas to detect a boundary (edge) between the two adjacent areas, but the technique disclosed in the present description is not limited to such an example. The line for edge detection can be set in any manner depending on the position of the boundary (edge) to be detected. For example, a curved line may be set, multiple lines may be branched from one line, or a line may be set across three or more adjacent areas to detect two or more boundaries (edges).

Although a specific example of the present disclosure has been described in detail above, this is merely illustrative and does not limit the scope of the claims. The technique described in the claims includes various modifications and changes to the specific example described above. The technical elements described in the present description or the drawings exhibit technical usefulness alone or in various combinations and are not limited to the combinations described in the claims as filed. In addition, the technique illustrated in the present description or the drawings can simultaneously achieve multiple objects, and the achievement of one of the objects inherently has technical usefulness.

1. A line setting device for setting lines in a captured image in which a component to be mounted by a component mounter is captured, the line setting device comprising:
a tentative line setting section configured to set tentative lines at multiple locations of the component based on a design value of the component;
a first captured image input section configured to input the captured image of the component;
a first determination section configured to, for each of the tentative lines at the multiple locations set by the tentative line setting section, determine whether a boundary between high-luminance pixels and low-luminance pixels is detectable with respect to a pixel group on the tentative line in the captured image input by the first captured image input section; and
an actual line determination section configured to not determine the tentative lines, for which the boundary is determined to be undetectable by the first determination section, as actual lines, and to determine the tentative lines, for which the boundary is determined to be detectable by the first determination section, as the actual lines.

2. The line setting device according to claim 1, further comprising:
a parameter adjustment section configured to, for each of the actual lines determined by the actual line determination section, adjust a parameter for detecting the boundary between the high-luminance pixels and the low-luminance pixels with respect to a pixel group on the actual line in the captured image input by the first captured image input section.

3. The line setting device according to claim 1, further comprising:
a second captured image input section configured to input another captured image different from the captured image input from the first captured image input section;
a second determination section configured to, for each of the actual lines set by the actual line setting section, determine whether the boundary between the high-luminance pixels and the low-luminance pixels is detectable with respect to a pixel group on the actual line in the captured image input by the second captured image input section; and
an output section configured to output a determination result by the second determination section.

4. A component mounter comprising:
a component supply section configured to supply a component;
an imaging device configured to capture an image of the component supplied by the component supply section;
the line setting device according to claim 1 configured to set lines in the captured image of the component captured with the imaging device; and
a component mounting section configured to mount the component supplied by the component supply section on a board,
wherein the component mounting section mounts the component at a mounting position, which is calculated based on the captured image of the component captured with the imaging device and the lines set by the line setting device.
